(19) United States
(12) Patent Application Publication
(10) Pub. No.: US 2010/0201362 A1
(43) Pub. Date: Aug. 12, 2010

(54) Method of improving magnetic resonance sensitivity

(76) Inventor: Bruce Holman, III, Milwaukee, WI (US)

Correspondence Address: Bruce Holman III, 7832 W. Lorraine Place, Milwaukee, WI, 53222, US

(21) Appl. No.: 12/658,542

(22) Filed: Feb. 11, 2010

Related U.S. Application Data
(60) Provisional application No. 61/207,478, filed on Feb. 12, 2009.

(51) Int. Cl. G01R 33/48

(52) U.S. Cl. 324/310

(57) ABSTRACT

We describe a method for use in enhancing MRI signals and increasing the sensitivity of NMR spectroscopy. The method involves the use of dynamic nuclear polarization (DNP) in which the polarizing agents are sequestered at the interface between two phases a sample phase, and a polarizing phase in such a way that the polarizing agent can be easily removed from the sample prior to analysis. The method produces much efficiency for sample manipulation, and the polarization process. In at least one embodiment the hyper-polarization can be repeated so as to allow the accumulation of spectra of the same material for further increasing the signal to noise ratio. The method also allows a discernment of which peaks in an NMR spectrum of a mixture belong to each individual component.

### CROSS-REFERENCE TO RELATED APPLICATIONS

This application claims the benefit of provisional patent application Ser. No. 61/207,478 filed Feb. 12, 2009.

### FIELD OF THE INVENTION

This invention relates to the field of nuclear magnetic resonance (NMR) spectroscopy specifically and to the associated technique of magnetic resonance imaging (MRI).

### BACKGROUND OF THE INVENTION

The following description is provided solely to assist the understanding of the reader. None of the references cited or information provided is admitted to be prior art to the present invention. Each of the references cited herein is incorporated by reference in its entirety, to the same extent as if each reference were individually indicated to be incorporated herein in its entirety.

Nuclear magnetic resonance (NMR) spectroscopy and its related technique magnetic resonance imaging (MRI) are methods of chemical analysis that can reveal information molecular structure and geometrical arrangement in space. Nevertheless the technique suffers from poorer sensitivity than might otherwise be the case because of the fact that the atoms available for analysis are only a fraction of those present in the sample as a whole. (see for example: “Spin Dynamics” by Malcolm H. Levit (John Wiley and Sons, Ltd. West Sussex, England) 2001). This is because the energy levels involved are so closely spaced that the number of molecules in the ground and excited spin state(s) are quite similar at room temperature. The difference in energy levels can be increased at considerable expense by employing stronger magnets, but even in ultra-high field magnets (21 T), the number of protons whose spin magnetic moment is oriented in the direction of the magnetic field is only 70 ppm greater than those polarized against (in the opposite direction of) the field. This small excess of ground state nuclei gives the sample only a small overall polarization in the direction of the magnetic field. Other efforts to increase the sensitivity of NMR include adding together the results of many spectra of the same sample so that the signal may be enhanced in comparison with random noise at the cost of longer analysis time. Particularly useful for this purpose is the popular use of the Fourier Transform (U.S. Pat. No. 3,475,680) method.

Recently the technique of dynamic nuclear polarization (DNP) has been used to increase the magnetic polarization of the sample, and thereby increase the sensitivity of the NMR experiment (“Mechanism of dynamic nuclear polarization in high magnetic fields,” J. Chem. Phys. 114, 4922-4933 (2001)). The technique involves the use of polarizing agents with one or more unpaired electrons which become more highly polarized by a magnetic field than most nuclei owing to the much larger gyromagnetic ratio of the electron compared with nuclei. This polarization can be transferred to the nuclei of the sample by radio frequency irradiation sufficient to induce transitions between the electron magnetic energy levels of the polarizing agent. Materials whose polarization has been enhanced over that at thermal equilibrium are referred to as hyperpolarized, and the process of producing this enhanced polarization is called hyper-polarization. Using this technique Ardenkjaer-Larsen et al [Proceedings of the National Academy of Science vol 100, pgs 10158-1063, (2004)] and J. Wolber et al [Nuclear Instruments and Methods in Physics Research A, vol 526, pgs 173-181 (2004)] demonstrated an increase in signal to noise ratio of >10,000 times in a liquid state NMR. This sensitivity increase was achieved by the use of a polarizing agent containing a stable free radical. Such a substance is said to be in a doublet electronic state. The doublet polarizing agent was dissolved in a solution of the substance to be analyzed, and the solution cooled to 1.5 Kelvin in a polarizing magnetic field of 3.35 Tesla. The cold solution was irradiated with radio frequency radiation at the Larmor frequency of the electron (94 GHz). Then the sample was warmed by the addition of room temperature solvent, and the spectra obtained within a few seconds after addition of the solvent. The irradiation step transferred the high polarization of the unpaired electron of the free radical to the nuclei of the sample and the hyper polarization was retained for several seconds while the sample was warmed and dissolved in the diluting solvent. However, the presence of the doublet state free radical during the subsequent analysis resulted in a broadening of the spectral lines of the sample making the technique of limited value to more complex chemical systems. Moreover, only a single spectrum of the sample could be taken without what has been called “considerable sample manipulation” (U.S. Pat. No. 7,205,764).

NMR spectroscopy is often performed on samples which are a mixture of more than one substance. For these samples the technique has the advantage that it is able to perform qualitative analysis, identifying the specific substance, and quantitative analysis, determining the relative amount of the substance present, with a single chemical analysis. But it is difficult to determine in a given mixture which spectral peaks come from a single chemical substance without specific knowledge about the types of molecules in the sample and their spectral characteristics. Thus it is often necessary to separate the individual components of a sample before the analysis thereby adding significant time and expense to the work. Some attempts at coupling NMR with liquid chromatographic techniques have been made since the first such report in 1978 (“Direct.Coupling of FT NMR to High Performance Liquid Chromatography,” Noriyuki Watanabe, and Eiji Niki; Proc. Japan Acad., 54, Ser. B (1978) [Vol. 54(B)]), but the separating action of the chromatography necessarily involves dilution of the sample by the eluting solvent. Also the use of large amounts of expensive deuterated solvents, or potential interference of the eluting solvent, has heretofore hampered a combined technique.

Molecules which contain two unpaired electrons in the same molecule are said to be in a triplet electronic state, and these materials have been employed to achieve greater polarization of the nuclei in an NMR sample. Materials which form a ground state triple have been reported to be useful for DNP by Griffin et al (U.S. Pat. No. 7,351,402). But here again when these triplet molecules are present during the spectral analysis of the sample they contribute to broadening of the spectral lines of the sample. Weston, et al [U.S. Pat. No. 7,205,764] and Hentstra [Chem. Phys. Letts, 165(1); 6-10 (1990)] have employed photochemically produced triplet states as polarization agents to increase NMR sensitivity. These materials have a finite lifetime as photoexcited molecules and return to the (singlet) groundstate after a short period of time. These materials have the advantage that by careful timing of the photochemical excitation, polarization, and spectral analysis processes, significantly less line broadening occurs. However, not all samples are stable to ultraviolet irradiation, and the technique requires expensive lasers, and optical equipment such as lenses and mirrors which must also be maintained, focused, and aligned.

### SUMMARY OF THE INVENTION

The invention relates to a method for increasing the sensitivity of NMR analysis, and for enhancement of the MRI image, by hyperpolarizing the sample for analysis or the contrast agents used to obtain the MRI image. The method especially improves the sensitivity of the NMR/MRI experiment for liquid samples such as those in which the sample of interest is dissolved in a suitable solvent. It presents a sample handling process that provides several unique efficiencies for the technique of dynamic nuclear polarization to hyper-polarize a sample thereby increasing the sensitivity of the experiment. The method accomplishes this without spectral line, broadening that occurs when the polarizing agent is present when the NMR spectrum is taken, or the use of expensive lasers and optical equipment.

Another object of some embodiments of the present invention is to provide a method by which the hyper-polarization can be reestablished and subsequent spectra obtained on the same sample. This makes possible the accumulation of many spectra of the same material which can be added together to further enhance the signal to noise ratio. A further object of certain embodiments is to reveal a method compatible with DNP that makes a convenient separation of the components of a mixture so that spectral peaks produced by each individual component of the mixture can be identified. The present invention overcomes these deficiencies by providing a quick and convenient way to separate the polarizing agent from the sample during the spectral analysis thus producing a spectrum with much sharper spectral lines. Moreover the method allows convenient establishment of intimate contact between sample and polarizing agent so that the hyper-polarization process is repeatable. These and other advantages of the present invention are attained in the method, which allows for enhancing the sensitivity of the NMR or MRI experiment.

In discussing the technique we refer to the sample as the material to be analyzed which may be in a pure form, or mixed with solvent or other components of a mixture. For many applications of the invention the sample will be in the form of a liquid or mixture in either neat form or in an appropriate solvent, but the technique may be applied to solid samples or mixtures as well. In most cases the hyper-polarization may be performed on the sample in one form (perhaps as a neat liquid, solid or mixture), and the spectral analysis performed on the sample in another form. For example the sample may be in the solid state during the polarization process and in a liquid solution when the spectrum is taken. It may be in the form of a mixture when polarized, but in a more purified form when the spectrum is taken, as some separation of components may be effected by the removal of the polarizing agent. Thus as in many analytical techniques the material to be analyzed may change form during the analysis process. It may start out as a solid mixture in a bottle, and end as a purified solution whose spectrum is observed. In each context the sample is the material undergoing manipulation at the time. Such usage of the term is common in analytical chemistry.

The method achieves the above stated objects by chemically bonding, strongly adhering to or otherwise sequestering the polarizing agent in a separate polarizing phase from that containing the sample. The polarizing agent is still able to effect polarization in the sample phase as long as the polarizing agent resides at or near the interface between the two phases when they are in contact. One advantage of attaching the polarizing agent to a separate phase is that separation from the sample phase can be easily effected by physical means such as filtering, washing, or settling.

### BRIEF DESCRIPTION OF THE DRAWINGS

FIG. 1 is a schematic summary of the method.

FIG. 2 is a diagram of the method in EXAMPLE 1 below.

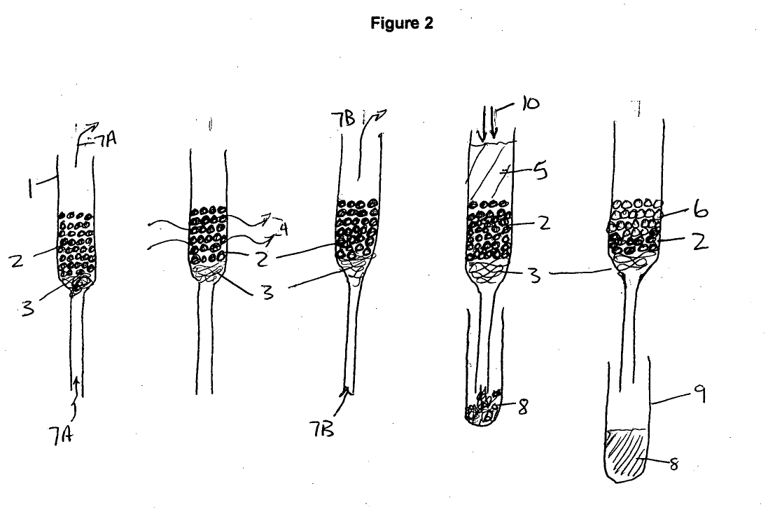

FIG. 3 is a diagram of the method in EXAMPLE 2 below.

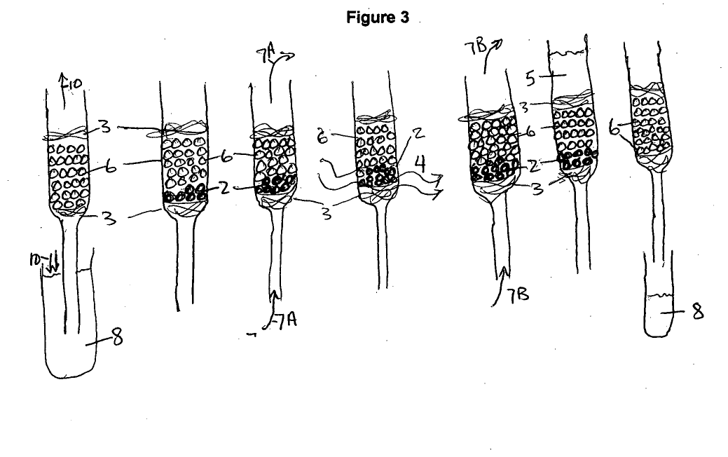

### LABEL LEGEND

1. 5 mm id syringe
2. TEMPO-bound silica with sample adsorbed
3. Glass wool filtering plug
4. Polarizing radiation
5. Solvent
6. TEMPO-bound silica with no sample on it
7. A. arrow showing flow of cold helium
7. B. arrow showing flow of warm helium.
8. Solution of sample and solvent
9. NMR tube with sample ready for analysis
10. Arrows showing direction of pressure gradient

### DETAILED DESCRIPTION OF THE INVENTION

Polarizing agents as mentioned in this document refer to materials which may be used in dynamic nuclear polarization which comprise chemical entities containing one or more unpaired electron, or which can be induced to produce one or more unpaired electron by the addition of sufficient energy such as by the action of light of appropriate wavelength. It will be appreciated that a variety of radicals may be attached to the surface of a particular phase. Examples of polarizing agents that have been used in dynamic nuclear polarization can be found in the references and include, but are not limited to: certain metal centers such as Cr⁺⁵, 2,2,6,6-tetramethyl-piperidin-1-oxyl (TEMPO) (ref.), 4-hydroxy-2,2,6,6-tetramethyl-piperidin-1-oxyl, 4-amino-2,2,6,6-tetramethyl-piperidin-1-oxyl, benzophenone, trityl radicals. Ideally polarizing agents most useful in the present invention are those which are or may be attached through chemical bonding, strong adherence, or otherwise sequestering at, near, or on the surface of the polarizing phase or interface between the polarizing phase and the sample phase. Examples of such chemical modification are given in: (Brunel, D.; Fajula, F.; Nagy, J. B.; Deroide, B.; Verhoef, M. J.; Veum, L.; Peters, J. A.; van Bekkum, H. Appl. Catal., A, 213, 73-82 (2001)) for the case of attachment of stable free radicals to silica or glass.

The polarizing phase may be solid, liquid or gas, but in any event must be not capable of dissolving in the sample phase, and have the capability of allowing the attachment of the polarizing agent to the surface in such a way that the polarizing agent comes in contact with the sample when the two phases are in intimate contact. Exemplifying this concept one embodiment involves the polarizing agent chemically bonded to a solid surface to form the polarizing phase. The polarizing agent can then be separated by removal of the solid phase from the sample by techniques such as, but not limited to: washing, rinsing, filtering, settling, or by otherwise selectively applying a mechanical force to the solid. In another embodiment the polarizing agent is in the form of a surfactant that resides to a significant extent at the interface of two immiscible liquid phases, one being the sample solution, the other being a polarizing phase. In this case the two liquids can be separated by settling and/or decantation.

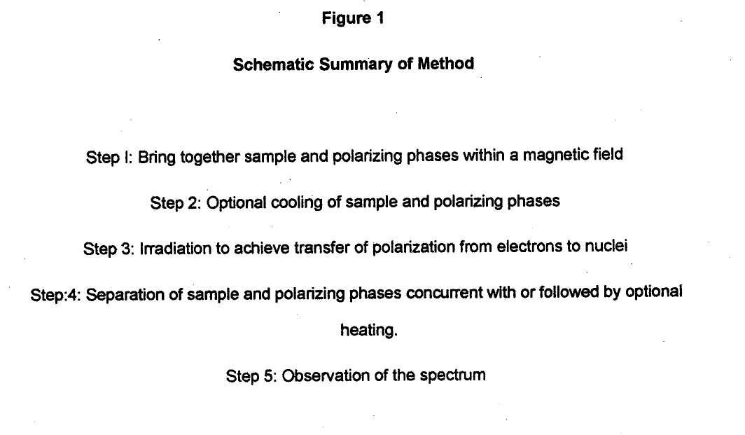

As shown in FIG. 1, the method involves bringing together the sample and polarizing phases in such a way as to achieve intimate contact between the two. At this point an optional cooling step may be appropriate, as a greater polarization is possible at lower temperatures. The sample and polarizing phases are then irradiated so as to transfer the polarization from the unpaired electrons to the nuclei of the sample. Again an optional heating step may occur at this point if the spectra is desired at a higher temperature than that for the polarization step. The heating step may occur simultaneously with or be aided by a dilution with a warm solvent. Or heating may occur to such an extent as to prevent the freezing of a solvent, and then a warm diluting solvent added so as to dissolve the sample, but not the polarizing phase. Finally a separation of the sample phase and the polarizing phase occurs by any number of physical processes such as filtering, settling, decanting, or selectively applying a mechanical force to one or the other phase.

In at least one embodiment the process of mixing, polarization, and separation can be carried out many times in rapid succession as many times as is needed for the required number of spectra to be accumulated. In other embodiments the process of separating the sample from the polarizing agent can also produce a partial or complete separation of the components of a mixture. Thus the technique can simplify the spectrum of a mixture by identifying the peaks that are produced by each component of the mixture.

The invention is described next by way of example of several embodiments. It will be understood that the invention is not limited to those examples or embodiments listed here. On the contrary, the invention includes all alternatives, modifications and equivalents as may be included within the spirit and scope of the appended claims.

### Example 1

In this example the polarizing phase is a solid phase with polarizing agent TEMPO chemically bonded to the surface of MCM-41 type silica particles. The preparation of several of these materials has been described in detail by Brunel et al (Brunel, D.; Fajula, F.; Nagy, J. B.; Deroide, B.; Verhoef, M. J.; Veum, L.; Peters, J. A.; van Bekkum, H. Appl. Catal., A 2001, 213, 73-82.). In particular, the TEMPO bound by an amide linkage to MCM-41 obtained by the reaction of 3-aminopropylsilylated MCM-41 and the N-hydroxysuccinimide ester of 4-carboxy-TEMPO in dry THF is useful. Enough of the silica to give a dry volume of 2.5 ml is combined with 0.5 mg naphthalene and 10 ml deutero-chloroform. The slurry is placed in a 25 ml round bottom flask and the chloroform is evaporated on a rotary evaporator. The TEMPO bound silica with the naphthalene adsorbed on its surface is placed in a 5 mm id glass syringe containing a glass wool filtering plug sufficient to hold the silica in place while allowing an organic liquid to pass through. The adsorbed sample is then cooled by a flow of cold He gas to below 77K, and the tube placed in a 9.4 T magnet and irradiated as described by Ardenkjaer-Larsen et al [Proceedings of the National Academy of Science vol 100, pgs 10158-1063, (2004)]. The sample is then warmed by a stream of room temperature He gas until it is warm enough so that it will not freeze chloroform. Then enough deutero-chloroform is added to the tube to cover the silica and provide a head of at least 2.5 ml in addition and the chloroform is forced through the silica until 2.5 ml of the sample laden solution has eluded into a 5 mm NMR tube. A single scan spectrum is taken immediately.

I claim:

1. A method comprising the steps of depositing a sample for NMR analysis on a polarizing phase; polarizing the sample; separating the sample from the polarizing phase; and then taking an NMR spectrum of the sample.
